(19) United States
(12) Patent Application Publication
(10) Pub. No.: US 2013/0140459 A1
(43) Pub. Date: Jun. 6, 2013

(54) SYSTEM AND METHOD FOR SAMPLE ANALYSIS BY THREE DIMENSIONAL CATHODOLUMINESCENCE

(71) Applicant: Simon Galloway, Oxford (GB)

(72) Inventor: Simon Galloway, Oxford (GB)

(73) Assignee: GATAN, INC., Warrendale, PA (US)

(21) Appl. No.: 13/309,425

(22) Filed: Dec. 1, 2011

(51) Int. Cl. H01J 37/26

(52) U.S. Cl. 250/310

(57) ABSTRACT

A system is disclosed for obtaining layered cathodoluminescence images of a sample wherein the light collecting equipment is highly efficient and wherein the microtoming or Focused Ion Beam equipment does not interfere with the efficiency of the light collecting equipment and wherein the position of the sample with respect to the light collecting equipment is not disturbed in the microtoming or ion beam milling process. Embodiments are disclosed allowing simultaneous collection of cathodoluminescence images and collection of other electron based imaging signals such as backscattered and secondary electrons.

### FIELD OF THE INVENTION

This invention relates to sample preparation and imaging in electron microscopy. In particular the invention relates to three-dimensional imaging of cathodoluminescence emitted by a sample.

### BACKGROUND OF THE INVENTION

Morphometry is an important and growing discipline within many spheres of biological science. Structural biologists require 3D information over extensive volumes. For example, in neuroscience, current models are based on real data obtained from serial sectioning brain tissue and subsequent reconstruction. Realistic and meaningful analysis requires morphometric analysis at the ultrastructural level over large sample volumes. Large volumes are required in order to be statistically relevant and usable for model building. Electron microscopy is key to providing information at the ultrastructural level.

Using electron microscopy, the classical method to obtain such data was serial sections collected on grids and observed in a transmission electron microscope (TEM). This is a long and difficult process requiring much skill. Sections are obtained as ribbons using an ultra-microtome. Ribbons must be divided manually. Multiple sections are then collected on grids.

Sections on grids are processed in various chemicals. All these steps are risky as the grids or sections can be broken. http://en.wikipedia.org/wiki/Ultramicrotomy.

Serial block-face scanning electron microscopy (SBFSEM) is a relatively new technique compared to the classical method mentioned above, whereby 3D information is gathered by sequentially scanning a freshly microtomed sample block face and the resultant multiple 2D images provide structural detail in 3D. With SBFSEM, the microtome operates in-situ in the electron microscope.

This method automates the cutting and subsequent imaging of the specimen. Grids are no longer used because sections are not cut for collection. It is the block of tissue itself that is directly introduced inside the scanning electron microscope and its surface is repeatedly shaved and scanned to obtain a stack of aligned images. The images collected through scanning depend on the contrast mechanism and therefore detector or detectors employed. A back scattered electron signal is commonly employed with the SBFSEM technique as this provides ultrastructure as revealed through staining techniques. The raw images obtained can be directly exported to software for reconstruction and quantification.

This technique called Scanning Block Face Scanning Electron Microscopy (SBFSEM) has been commercialized by Gatan® under the trade name 3View® . In this technique, structural information about the specimen is typically gathered by imaging with a back scattered electron signal. A relevant paper is this field is by W. Denk and H. Horstmann entitled “Serial block-face scanning electron microscopy to reconstruct three-dimensional tissue nanostructure”. Plos. Biology, 2004.2(11): pp. 1900-1909. Additional references describing the use of SBFSEM include: H. E. J. Armer et al., “Imaging Transient Blood Vessel Fusion Events in Zebrafish by Correlative Volume Electron Microscopy.” Plos. One 4(11), November 2009: p. 4.; John B. West et al., “Structure-Function Studies in Blood and Air Capillaries in Chicken Lung Using 3D Electron Microscopy.” Respir Physiol Neurobiol, 2010 Feb. 28 170 (2): p. 204; Xiaokun Shu et al., “A Genetically Encoded Tag for Correlated Light and Electron Microscopy of Intact Cells, Tissues, and Organisms.” Plos. Biology, 2011 9(4): pp. 5, 6; Thomas Müller-Reichert et al., “Three-Dimensional Reconstruction Methods for Caenorhabditis elegans Ultrastructure.” Methods in Cell Biology Vol. 96, 2010: pp. 348-49; Armin Zankel et al., “3D Elemental Mapping in the ESEM.” G.I.T. Imaging & Microscopy February 2011: pp. 2-4; Jacques Rouquette et al., “Revealing the High-resolution Three-dimensional Network of Chromatin and Interchromatin Space: A Novel Electron-microscopic Approach to Reconstructing Nuclear Architecture.” Chromasome Research (2009) 17:801-810.; and Debarshi Mustafi et al., “Defective Photoreceptor Phagocytosis In a Mouse Model of Enhanced S-Cone Syndrome Causes Progressive Retinal Degeneration.” FAESB J. 25: pp. 3157-3176 (2011). All references cited herein are incorporated by reference.

It is possible to implement this technique in a range of scanning particle instruments since the core principle is based on the automated sequential removal of a surface layer of a block face followed by imaging. In a related scanning technique, the specimen is sequentially milled by an energetic charged focused ion beam (FIB) to reveal a fresh plane of a block face for subsequent imaging by scanning a focused electron beam. This process is described in the Müller-Reichert and Armer publications cited above. This sequential approach is used to build a 3D data set of the imaged volume of the specimen. Again, with this technique, structural information is gathered by imaging with the back scattered electron signal. This is a competing approach to the 3View® (SBFSEM technique) for performing 3D structural microscopy in a scanning microscope, since with both approaches a thin layer is removed in-situ and the freshly revealed block face is imaged. With the 3View® approach, the volume of material that can be cut in an automated fashion is much greater than using this FIB approach, which is typically slower per unit volume of material removed.

Kristina D Micheva and Stephen Smith, (US Patent application 20080152207, Jun. 26 2008). have described a technique for 3D imaging from a bulk specimen whereby the specimen is first cut into thin sections. Each section is imaged away from and independent of the cutting equipment, and then recombined to form a 3D data. This patent describes the collection of various signals as a result of the energized stimulation including cathodoluminescence. In this array technique, the sections which are cut away from the bulk specimen are imaged in an array. In this approach, there is more emphasis on software to re-align images in a sequence to form the 3D image. In this approach, the imaging takes place after all the cutting has been performed, not after each cut.

Related to the Micheva/Smith technique is serial sectioning, imaging and subsequent reconstruction in the TEM. This technique is similar to that described above in that it is the cut sections which are prepared and then imaged in order to provide the ability recombine them to form 3D information.

Optical microscropy techniques can provide fluorescence imaging in 3D by using a confocal approach. The depth in the specimen which provides the 2D image is controlled by the localized focusing of the light stimulation. This technique is different in that the stimulation is by photons, and the specimen is not cut to provide information in the third dimension.
http://en. wikipedia.org/wiki/Two-photon_excitation_microscopy

It is possible to obtain some depth and therefore 3D information using Cathodoluminescence from bulk specimens from comparing the 2D images recorded at different accelerating voltages of the stimulating beam. F. K. Toth et al, “Depth Profiling of GaN by Cathodoluminescence Microanalysis”, in 74 Applied Physics Letters 8 pp. 1114-16 (February 1999).

At low energies, the signal emerges from material closer to the irradiated surface than it does when using a higher energy beam wherein the signal emerges from a range of depths. This technique is different from that described herein since the depth of penetration is limited, the deconvolution of information leads to losses in 2D resolution, and because the same surface area needs to be irradiated multiple times. This makes the technique unsuitable for beam sensitive specimens such as resin-embedded material which is the primary subject contended for the 3D CL invention.

### Description of Cathodoluminescence

Cathodoluminescence is the light created by stimulation using energetic electrons. The definition has also been relaxed to apply to the creation of light stimulated by other energetic particles. This definition does not extend to stimulation by photons, even though the term fluorescence is sometimes used to describe the act of light emission without reference to the act of stimulation.

With cathodoluminescence, the electrons or charged particles can be focused to a beam or remain unfocused to cover an area of interest. The stimulated light is measured as the beam is located at a defined position, rastered over an area, or illuminates an area of interest in an unfocused manner. The wavelength of photons associated with Cathodoluminescence typically ranges from 180 nm to 3000 nm. The local intensity, spectroscopic make-up and transient behavior of the light with regard to the period of stimulation can be analyzed, for example the onset of luminescence, the decay of luminescence, or the growth or quenching behavior associated with changes stimulated by the electrons/charged particles. Cathodoluminescence can be associated with components which are intrinsic or extrinsic to the specimen. Cathodoluminescence can also be studied as a function of the specimen temperature. An intrinsic luminescence could be a background luminescence, whilst an extrinsic feature can be associated with an intentional marker or label.

Cathodoluminescence from a bulk specimen can take place in a high vacuum or low vacuum conditions associated with the scanning electron microscope, or FIB instrument. The bulk specimen contains intrinsic or extrinsic features which luminesce in response to the stimulation. These features extend into the depth of the specimen, but only those in proximity to the surface compared to the penetration depth of the stimulating energetic beam are caused to luminesce. The collection of luminescence forms the basis of a 2D image. This technique is standard and has been practiced for many years. Cathodoluminescence can only be collected from underneath the specimen where the bulk of the specimen is transparent to the wavelength of the light, and if the specimen holder which supports the specimen is also transparent. For example in the paper below, simultaneous CL and BSE are collected (FIG. 6) from a wet specimen in a conventional SEM. The specimen is enclosed in a capsule. An electron transparent thin film separates the wet specimen from the chamber vacuum, and a light guide is inserted into the bottom of the capsule. The liquid couples the light from the stimulated area through to the fiber optic in the base of the capsule. Stephan Thiberge et al, “Scanning electron microscopy of cells and tissues under fully hydrated conditions” in 101 PNAS 10, pp. 3346-51 (Mar. 9, 2004).

An important aspect of collecting a 3D data set in this manner is that unlike confocal or transmissive techniques, the spatial resolution obtained in each 2D image does not diminish as a function of depth since each acquisition is from a fresh block face.

The luminescence usually has no favored directionality. However, the light emission from the specimen will have strongly favored directionality because of the effect of total internal reflection in the specimen. For a specimen with a flat surface, the light emission distribution always follows Lambertian distribution, which means that the intensity peaks normal to the surface.

Most specimens suitable for cutting with a microtome or milling will be sensitive to the dose by the stimulant. Therefore the design of the equipment to optimize the light collection efficiency is important to the success of the technique. It is not sufficient to have poor collection efficiency using optics which present a poor solid angle to the luminescence source. This is because the energy and dose of the stimulation needs to be kept low in order to achieve the desired resolution in X,Y and Z and also in order to maintain the structural integrity of the medium to be cut. For this reason the design of the collection optics is an important consideration.

There is a need, therefore, for a system for obtaining layered cathodoluminescence images of a sample wherein the light collecting equipment is highly efficient and wherein the microtoming or Focused Ion Beam equipment does not interfere with the efficiency of the light collecting equipment and wherein the position of the sample with respect to the light collecting equipment is not disturbed in the microtoming or ion beam milling process.

### SUMMARY OF THE INVENTION

The invention is directed to an apparatus for imaging cathodoluminescence from a specimen in 3D using an electron microscope.

In an embodiment, the microtoming apparatus is adapted to reflect the cathodoluminescence to a light detector after making a cutting pass across the specimen. The microtome is further adapted to allow the cathodoluminescence imaging to take place in synchrony with collection of the back scattered signal. In a further embodiment an alternative adaption is to allow the cathodoluminescence imaging to take place in synchrony with the collection of secondary electrons.

In a further embodiment, the microtome is transparent and the cathodoluminescence is reflected to the light detector total internal reflectance within said microtome. In a further embodiment, the microtome is mounted on a support containing integral light detectors and the cathodoluminescence is detected while the microtome is passing across the specimen. In a further embodiment, the light detectors comprise a plurality of filters for simultaneous measurement of different wavelengths of light.

In a further embodiment, the light detector is mounted in a support for the microtome and in the path of an electron beam of the electron microscope.

In a further embodiment, the specimen and a specimen support are at least partially transparent and the light detector detects light internally reflected by the specimen support. In a further embodiment of this configuration, there is a highly reflective surface positioned above the specimen to enhance the amount of light reflected to the light detector.

In a further embodiment, the apparatus includes a mirror and a mirror actuator, and the mirror actuator positions the mirror to reflect the cathodoluminescence to the light detector after the microtome has passed across the specimen. In a further embodiment of this configuration, the mirror actuator is attached to the pole piece of the electron microscope or to the microscope chamber.

In a further embodiment, the specimen is optically transparent and has a milled face cut by the microtome and an opposite face parallel to the milled face and the light detector is positioned to receive light emitted at the opposite face. In a further embodiment of this configuration, there is included a reflector positioned to reflect light emitted by the milled surface back into the specimen.

In a further embodiment, there is a microtome support and a fiber optic mounted to the microtome support, wherein the fiber optic directs light to the light detector while the microtome is passing across the specimen.

In a further embodiment there is a remotely actuated fiber optic holder, wherein the holder is actuated to place a fiber optic to collect light from the specimen after the microtome has passed across the specimen.

In a further embodiment the specimen includes reflective surfaces to reflect light to the photo detector.

In a further embodiment, the apparatus includes a linear carriage, a dead stop and a mirror, wherein the microtome and mirror are mounted in and moved along the linear carriage and wherein the mirror is positioned against the dead stop when the microtome has completed a pass across the specimen.

In a further embodiment of the invention, there is an apparatus for simultaneous imaging of backscattered electrons and cathodoluminesence from a specimen in an electron microscope and the apparatus includes: a focused ion beam (FIB) generator, a light director; a light detector; a backscattered electron detector. The FIB generator directs a beam to mill a surface of the specimen and the light director is positioned to direct light from the specimen surface to the light detector after the beam has milled the surface. In a further embodiment of this configuration, the beam also mills structures for reflecting light to the light director and a reflective surface is deposited onto surfaces of the milled structures by introduction of localized gas in combination with the FIB.

### DESCRIPTION OF THE DRAWINGS

FIG. 1. is a diagram of an embodiment having an integral knife holder and photon guide or detector;

FIG. 2. is a diagram of an embodiment having an integral knife holder and photon guide or detector, further adapted to collect secondary electrons, for example using an in-lens secondary electron (SE) detector;

FIG. 3. is a diagram of a further embodiment having an integral knife holder and photon guide or detector;

FIG. 4. is a diagram of an embodiment wherein the knife itself is the light-guiding device;

FIG. 5. is a diagram of an embodiment wherein the solid angle is shared between a cathodoluminescence mirror and a back scattered electron detector;

FIG. 6. is a diagram of an embodiment wherein the knife holder contains an integral light detector;

FIG. 7. is a diagram of an embodiment wherein a light collection mirror is mounted to return automatically to an accurately reproducible position after the knife has cleared the specimen area;

FIG. 8. is a diagram of a further embodiment wherein a light collection mirror is mounted to be returned to an accurately reproducible position after the knife has cleared the specimen area;

FIG. 9. is a diagram of an embodiment wherein the specimen and the specimen support are partially optically transparent and wherein the light detector and the knife are on opposite sides of the specimen;

FIG. 10. is a diagram of an embodiment wherein a fiber optic light collector is part of the moveable knife and light collection apparatus;

FIG. 11. is a diagram of an embodiment where the knife includes fixing points for optical fibers terminated close to the specimen;

FIG. 12. is a diagram of a further embodiment wherein a light collection optical fiber is mounted to be returned to an accurately reproducible position after the knife has cleared the specimen area;

FIG. 13. is a diagram of a further embodiment wherein the specimen is prepared to include light reflecting surfaces for directing light to a detector;

FIG. 14. is a diagram of an embodiment comprising a Focused Ion Beam for milling a specimen surface and wherein light detection equipment is fixed in relationship to the specimen;

FIG. 15. is a diagram of an embodiment comprising a Focused Ion Beam for milling a specimen surface and wherein the FIB creates a reflecting surface on the specimen in situ; and

FIG. 16. is a diagram of an embodiment wherein a knife arm is cleared by a motor and this pulls a CL collection mirror into a position defined accurately by a dead stop for remote light collection or detection;

FIG. 17, is a diagram of an embodiment of the design disclosed in FIG. 8, wherein a highly reflective surface 17 is placed above the specimen 30 at the time that light is collected.

### DETAILED DESCRIPTION

Several embodiments of the invention are directed to obtaining a 3D CL data set through sequentially imaging and microtoming a block face. When performed in an automated fashion, voxels of dimension X, Y, Z are acquired, whereby the Z dimension is influenced by the thickness of each sequential cut to the block. With multiple detectors and analysis techniques, each voxel can be associated with structural, chemical, elemental and luminescence information.

Embodiments of the invention disclosed here relate to the equipment which allows the cutting, the imaging, and the collection of the emitted CL light signal in synchrony, or with the option of being in the same sequential acquisition as other signals providing matching structural information. In various embodiments, different types of CL signals can be collected with high efficiency, and simultaneously with other signals associated with the stimulating beam in the confined space of the instrument. High efficiency is required since photons are in short supply when the injection conditions are optimized for maximizing spatial resolution in either 2D or 3D. Moreover, using novel light collection optics prevents the need for a macroscopic movement of the specimen in the X, Y or Z direction in order to switch between imaging to collect luminescence, imaging to collect other structural signals, or cutting. If such movement were to be incurred, it would introduce potential misalignments in the 3D data set and require post processing re-alignment. Novel light collection techniques also enhance the resolution of the technique since this allows use of shorter working distances, and lower accelerating voltages, (which are directly linked to spatial resolution in a scanning electron microscope). In a low vacuum electron microscope, they are also associated with lower losses associated with scattering by gas molecules.

The following embodiments disclose optical devices for in-situ collection of light emitted from the freshly revealed block face, that do not interfere with the fundamental operation of the 3D acquisition techniques, whether this is achieved through in-situ microtomy: Scanning Block Face Scanning Electron Microscopy (SBFSEM) or FIB milling.

Certain embodiments disclose ways to collect light with high efficiency without moving the specimen a macroscopic distance, such as using the SBFSEM technique based on in-situ microtomy while using the mechanical movement of a knife between successive images. CL light is either collected and redirected towards light detection equipment which is remote from the specimen, or else detection sensors are positioned in suitable locations in close proximity to the specimen either permanently, or temporarily through a controlled manner. The presence or introduction of light collection, light coupling or light detection equipment does not interfere with the general performance of the instruments as a tool for sequentially cutting or milling specimens in-situ. When light is redirected, e.g. using a mirror or light pipe, the light detection equipment can be inside the microscope chamber, or attached to the outside, or else relatively remote to the chamber.

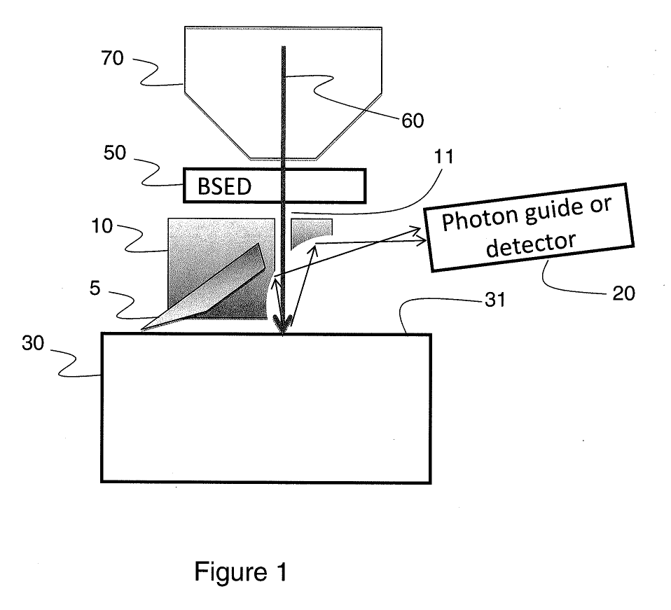

FIG. 1 shows an example of an embodiment of an electron microscope wherein the microtome knife 5 is mounted on knife holder 10, which is shaped to be the reflective optical component that directs light emitted at the surface 31 of the specimen 30 to the light detector 20.

In this embodiment, the knife holder/reflector has a hole 11 through the reflecting portion. This allows a clear path for the primary electrons 60 to the specimen. The knife/reflector is moved across the specimen 30 to expose a new layer and then momentarily stopped at the end of the cut to allow the freshly revealed surface to be scanned by the particle beam, with the resultant specimen luminescence to be reflected and imaged by the photon detector 20. This process is repeated to collect a 3D CL image.

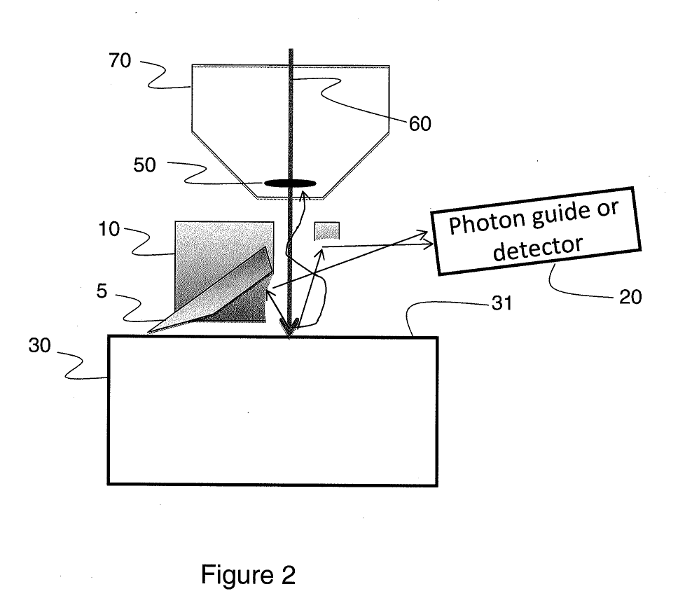

FIG. 2 shows a variation of the embodiment in FIG. 1, wherein the mirror of the knife holder 10 is shaped for more efficient simultaneous collection of other electron-based signals, for example, using an In-Lens Secondary Electron Detector 50.

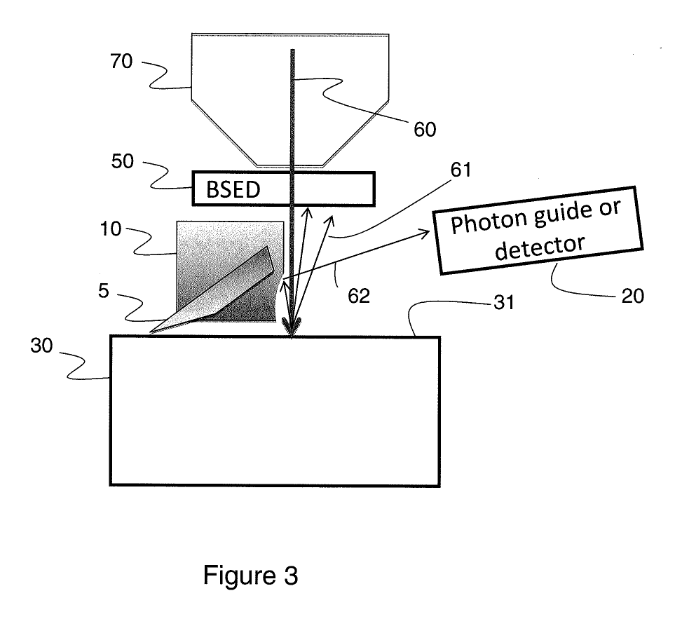

FIG. 3 is a further variation of the embodiments of FIGS. 1 and 2, wherein the knife holder/reflector 10 is shaped to share the solid angle to allow simultaneous imaging of CL 62 by the photon detector 20 and BSE 61 by the BSE detector 50.

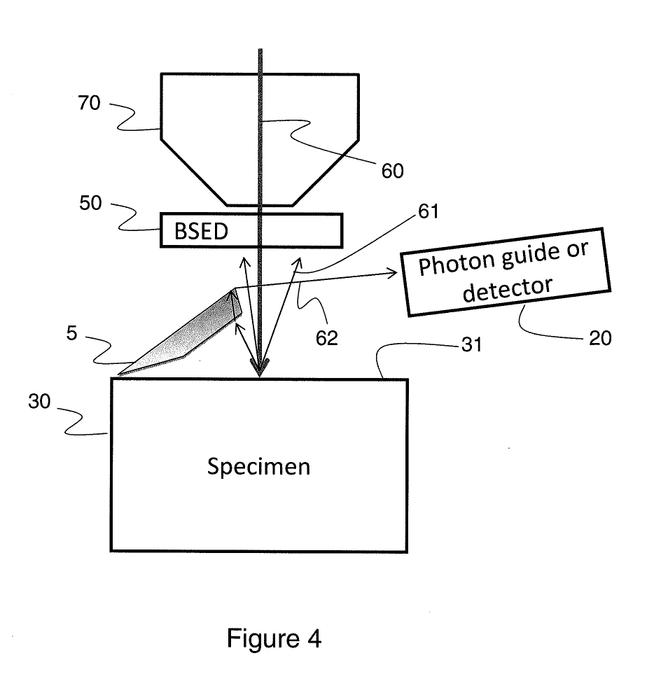

FIG. 4 shows an example of an embodiment wherein total internal reflection within the knife 5 directs light 62 from the specimen surface 31 to the detector 20 after the knife has traversed across the specimen face to make a cut.

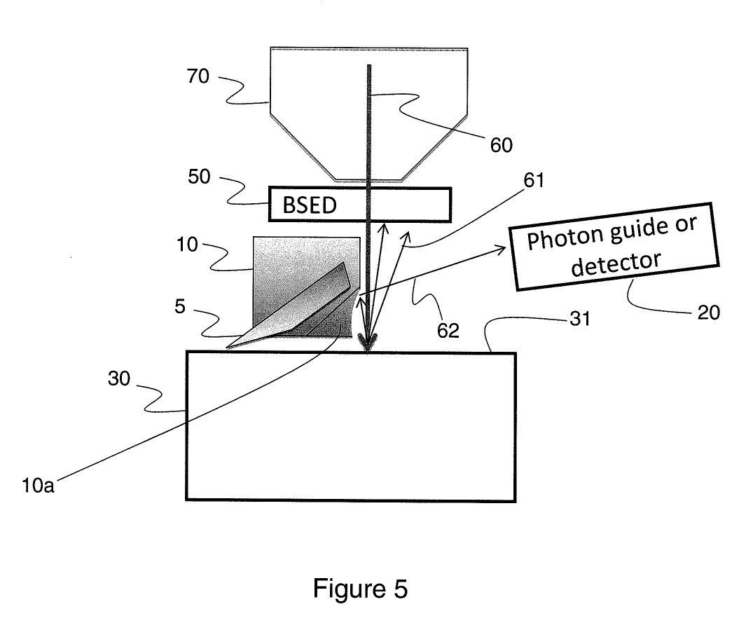

FIG. 5 shows an example of an embodiment where the knife holder 10 contains a mirror. In this embodiment the knife holder contains a sub component 10a, which is a reflector. In an embodiment of the apparatus shown in FIG. 5, the knife holder is steel and the mirror 10a is aluminum.

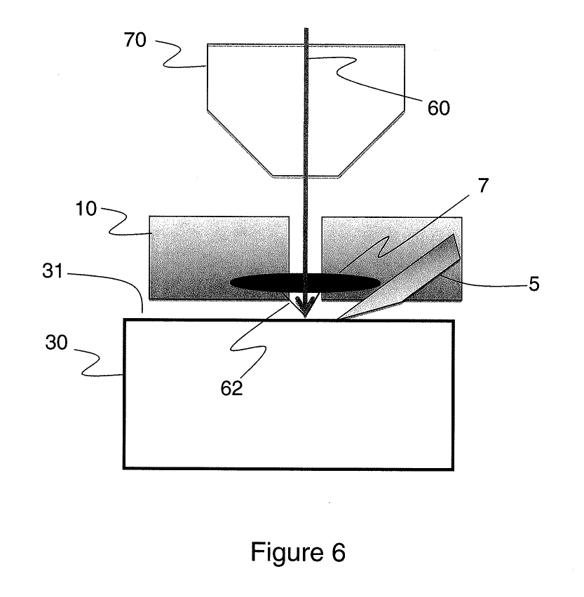

FIG. 6 shows an example of an embodiment wherein the knife holder 10 contains one or more integral light detectors 7 that share the same precision movement apparatus as the knife 5 and thus provide stable repeatable positioning for each cutting pass across the sample face 31. Multiple detectors can include detectors with different bandwidth filtering for measuring different colors simultaneously. An optically transparent, electrically conductive film is used on the light detector to block electrons and only measure the light signal. This can serve as a static detector of luminescence which is sufficiently thin to allow the diamond knife to pass beneath without significantly increasing the working distance. If part of the detector has multiple segments, and only part of it is configured with a thin film, then it can act as a simultaneous luminescence and back scattered electron detector. If the films have specific colored filters then these can be used to record the position of different colored labels.

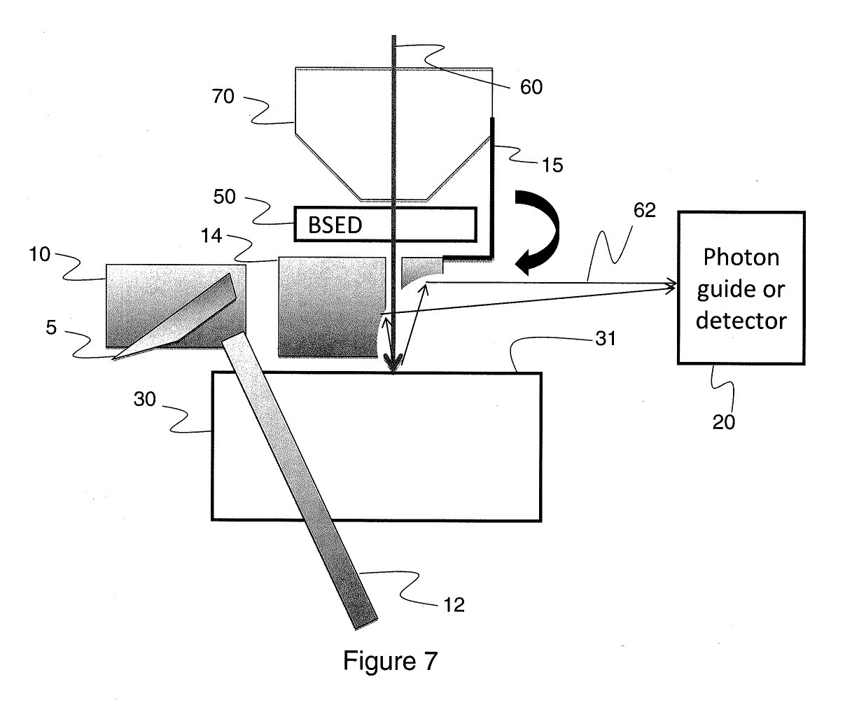

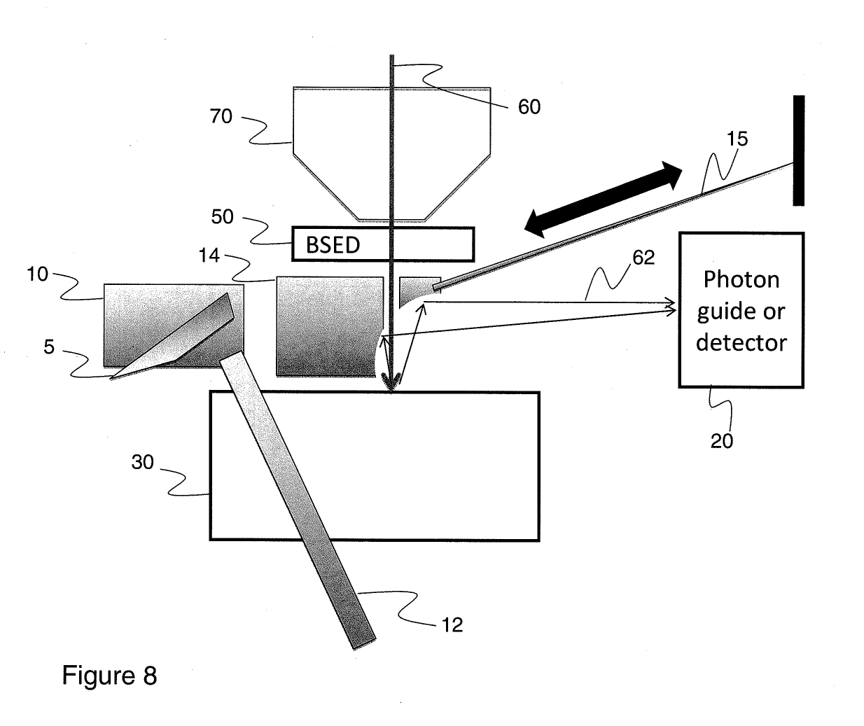

FIG. 7 shows an example of an embodiment wherein the mirror 14 is not mounted to the knife holder 10, but to an actuator 15, mounted in this example to the microscope pole piece 70. In this embodiment, the knife holder 10 is moved by a separate actuator 12. The mirror actuator 15 can also be mounted to any other fixed structure, including the chamber wall, roof or floor, the chamber ports, or the microtome body. When attached to a fixed structure, the holding mechanism employs motorized hardware which automatically positions and then subsequently removes the mirror from an optimum position for light collection. When the knife 5 has completed a pass across the specimen face 31, the second actuator 15 accurately positions the mirror 14 over the specimen 30. When removed, the mirror does not interfere with the cutting action of the instruments. Photons are then reflected to the detector 20 as in the previous embodiments. An aspect of this embodiment is the need for a very accurate positioning actuator for the mirror 14. As in previous examples, cutaways 11 in the mirror 14 can enable simultaneous collection of multiple signals. In this example the mirror actuator 15 is mounted to the pole piece 70. In a further embodiment, an example of which is shown in FIG. 8, the mirror actuator 15 is mounted to a remote point like the chamber wall 16. The translation mechanism in this case is linear as opposed to rotational as in the example shown in FIG. 6.

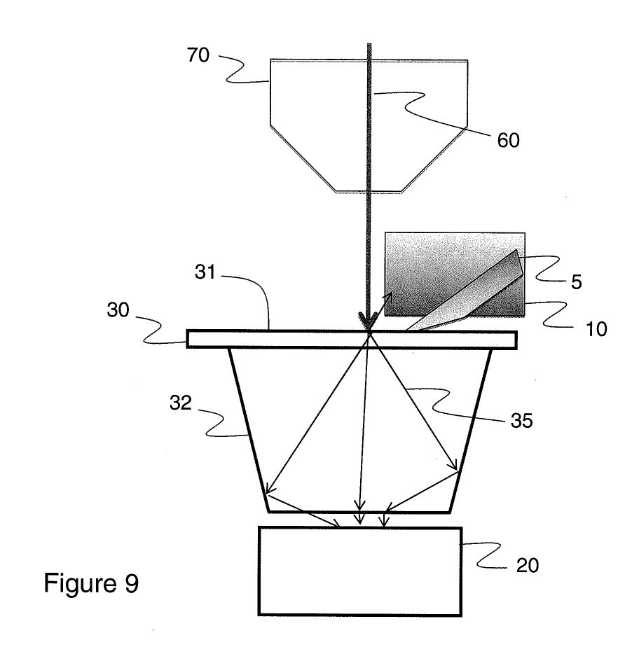

FIG. 9 shows an example of an embodiment wherein the specimen 30 and specimen support 32 are partially optically transparent. In this embodiment, a photon guide or detector is placed at the opposite end of the specimen from the microtomed surface 31. In this example, the side walls of the specimen and the support are reflective to aid in total internal reflection of the CL light 35, thus increasing the efficiency of the light detection.

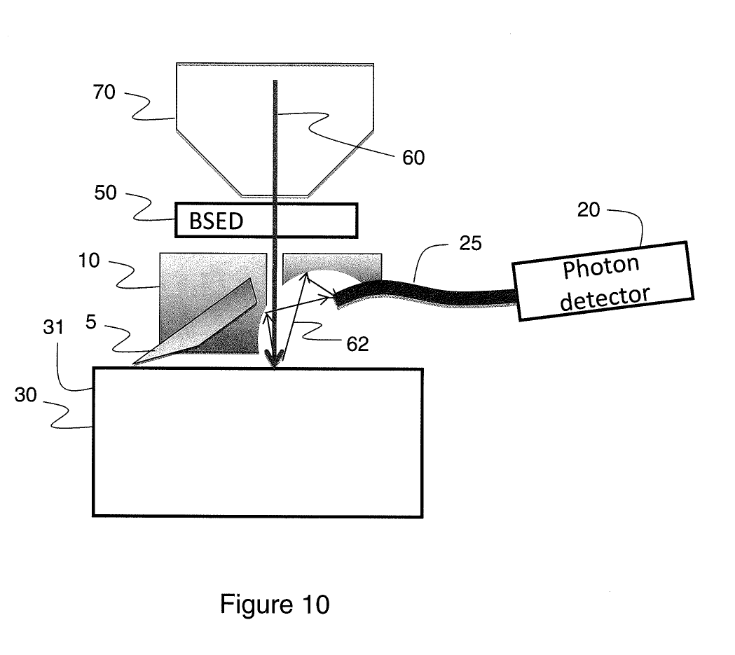

In a further embodiment, shown in FIG. 10, a light collecting tube, fiber optic hose, or fiber optic bundle 25 is brought into close proximity to the specimen during imaging. The microscope is either used in low vacuum mode, or else the light collection components are given an optically transparent electrically conductive coat so as not to introduce electrostatic fields. The optical guiding hardware is either attached permanently to a fixed structure but out of the way of the knife, or is attached to the knife holder, and shown in FIG. 10, and stops in the correct position, or else is brought in mechanically to an optimum position, and removed again between the imaging and cutting actions.

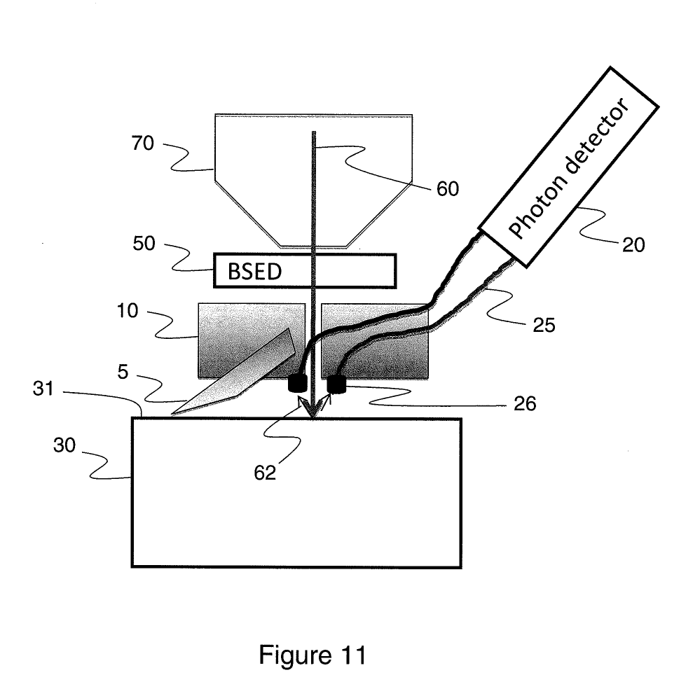

In a further embodiment, an example of which is shown in FIG. 11, the knife holder 10 includes fixing points 26 for one or more fiber optics 25 to be terminated close to the CL emission point of the specimen 30. This increases the coupling efficiency of light to the detector.

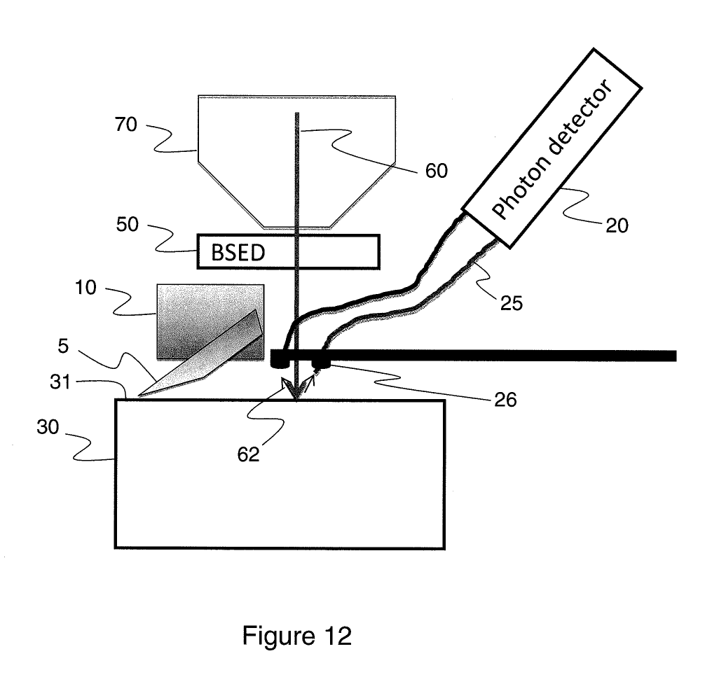

In a further embodiment, shown in FIG. 12, a remotely-attached support 26 contains fiber optics 25 as in FIG. 11, except that the support is separately actuated into place after the knife holder 10 has cleared the specimen surface area 31.

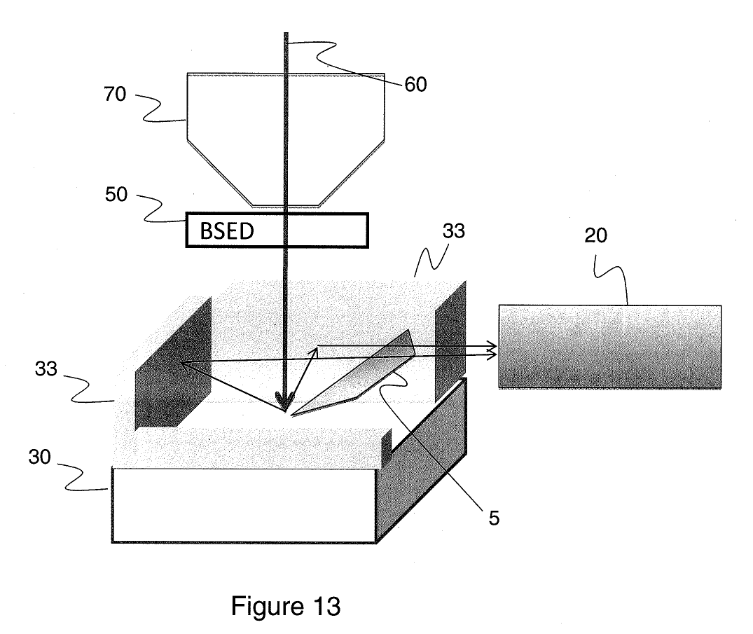

In a further embodiment, an example of which is shown in FIG. 13, the specimen 30 is pre-prepared to provide structures 33 coated with a reflective layer so that light emitted from the milled surface 31 of the specimen is directed towards a light collector or detector 20.

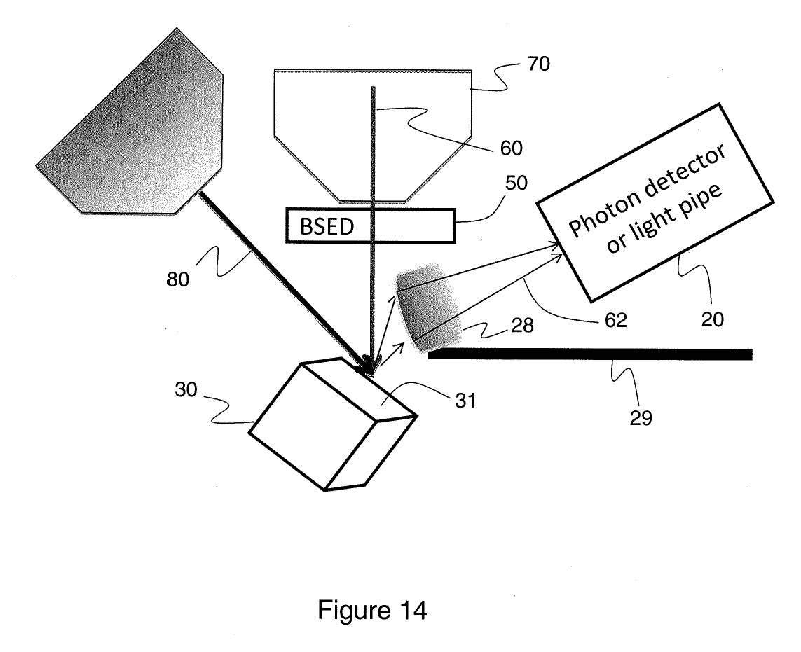

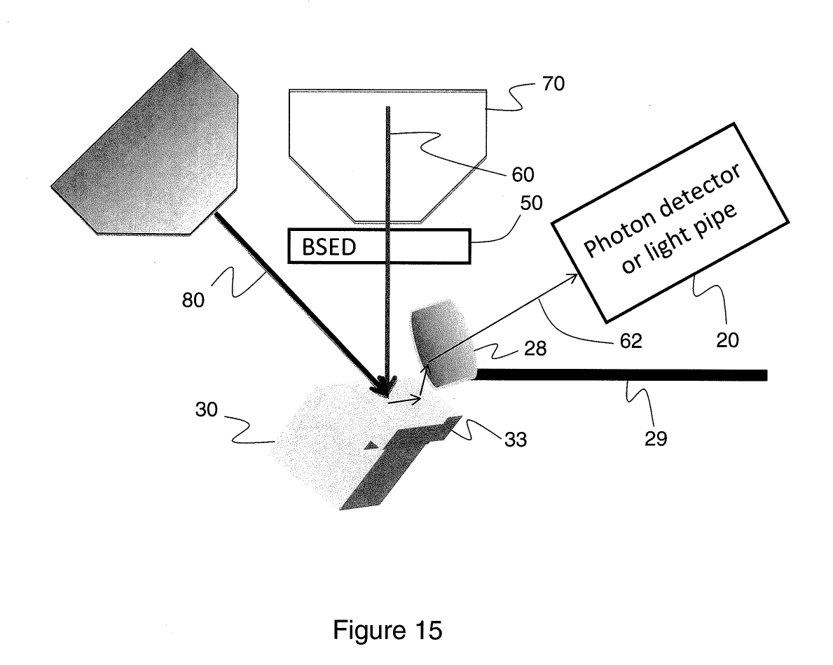

FIGS. 14 and 15 depict exemplary embodiments wherein the specimen is not milled with a knife, but with a focused ion beam (FEB). In FIG. 14, the FIB 80 is directed to the surface 31 of the specimen 30 to mill fresh layers. FIG. 14 also shows a separate light directing structure 28, to direct light to the detector or light pipe 20. The light directing structure can be attached to a fixed portion of the microscope because there is no need to move out of the way of the specimen surface where the surface is milled with an FIB, such that the FIB and the equipment to produce it can reach the specimen surface without interfering with the emission of surface light.

In the exemplary embodiment shown in FIG. 15 the specimen 30 is milled in-situ to create a light coupling structure 33, such as is discussed above and illustrated in FIG. 13. In a further embodiment, a combination of the ion beam and localized gas injection deposits a reflective coating on the milled light coupling structures 33.

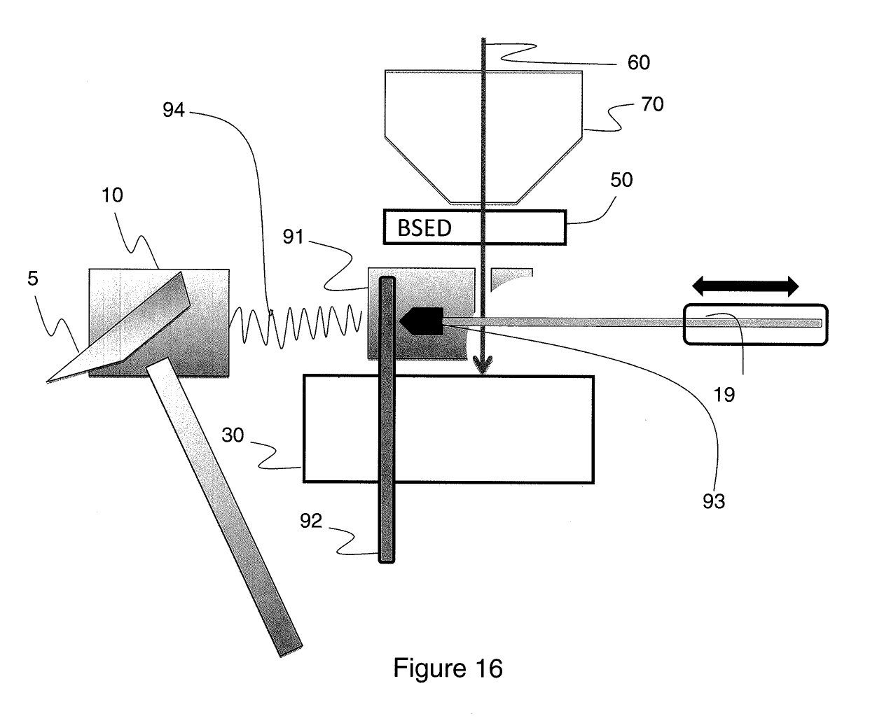

In a further embodiment shown in FIG. 16, the microtome knife 5 and knife holder 10 cut the specimen 30 by means of actuation (not shown), and after cutting are moved to a remote location in a fashion similar to FIG. 7. A mirror mechanism 91 is rigidly attached to a linear rail 19 and this mechanism includes a hard locator 93. The knife holder 10 is coupled to the mirror mechanism by means of a spring 94. When the knife holder 10 is cleared away from the specimen face after each cut, the movement pulls the point on the mirror into position against a dead stop 92. When cutting the knife holder pushes the mirror on the linear rail out of the way. The combination of the rail and the dead stop provide accurate and repeatable positioning of the mirror 91 using just one actuator movement.

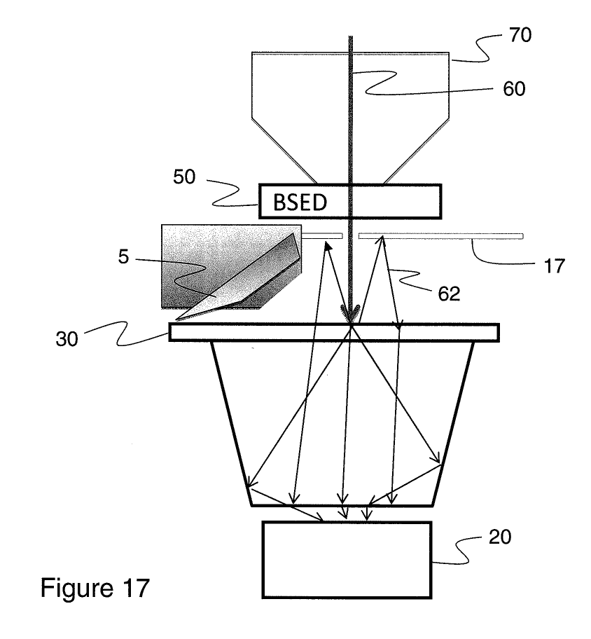

FIG. 17, shows an example of a further embodiment of the design disclosed in FIG. 8, wherein a highly reflective surface 17 is placed above the specimen 30 at the time that light is collected. This reflective surface increases light-collecting efficiency by reflecting any light 18 that is emitted upward back down through the specimen 30 to the photon guide or detector 20. The highly reflective surface contains an aperture to allow backscattered electrons to reach the BSE detector 50.

In a further embodiment a lens is used to enhance the solid angle of light collected into a more remote light detecting equipment. The lens can be fixed in an optimum position, attached to the knife holder in an optimum position, or else attached to an arm which is repositioned mechanically and automatically between imaging and cutting.

Note that in all cases employing a mirror, additional cutouts can be provided in the mirror surface which sacrifice some of the potential solid angle and light collecting efficiency, but which provide simultaneous collection using other imaging signals such as back scattered or secondary electron signals.

While the invention has been described in detail and with reference to specific examples thereof, it will be apparent to one skilled in the art that various changes and modifications can be made therein without departing from the spirit and scope thereof.

We claim:

1. An apparatus for imaging of backscattered electrons and cathodoluminescence from a specimen in an electron microscope, comprising:
a microtome;
a light detector; and
a backscattered electron detector;
wherein said microtome is adapted to reflect the cathodoluminescence to said detector after making a cutting pass across the specimen and wherein said microtome is further adapted to not interfere with the detection of backscattered electrons by said backscattered electron detector.

2. The apparatus of claim 1, wherein said microtome comprises a mounting structure with a mirror for directing the cathodoluminescence to said light detector.

3. The apparatus of claim 2, wherein said mirror shares a solid angle with said backscattered electron detector.

4. The apparatus of claim 1, wherein said microtome is transparent and the cathodoluminescence is reflected to said light detector by total internal reflectance within said microtome.

5. The apparatus of claim 1, wherein said microtome is mounted on a support containing integral light detectors and wherein the cathodoluminescence is detected while said microtome is passing across the specimen.

6. The apparatus of claim 5, wherein said light detectors comprise a plurality of filters for simultaneous measurement of different wavelengths of light.

7. The apparatus of claim 1, further comprising a mirror and a mirror actuator, wherein said mirror actuator positions said mirror to reflect the cathodoluminescence to said light detector after said microtome has passed across the specimen.

8. The apparatus of claim 7, further comprising an electron emitting pole piece and a chamber and wherein said mirror actuator is attached to either said pole piece or to said chamber.

9. The apparatus of claim 1, wherein said specimen is optically transparent and has a milled face cut by said microtome and an opposite face parallel to said milled face and wherein said light detector is positioned to receive light emitted at said opposite face.

10. The apparatus of claim 9, further comprising a reflector positioned to reflect light emitted by said milled surface into the specimen.

11. The apparatus of claim 1, further comprising a microtome support and a fiber optic mounted to said microtome support, wherein said fiber optic directs light to said light detector while said microtome is passing across the specimen.

13. The apparatus of claim 1, further comprising a remotely actuated fiber optic holder, wherein said holder is actuated to place a fiber optic to collect light from the specimen after said microtome has passed across the specimen.

14. The apparatus of claim 1, wherein the specimen includes reflective surfaces to reflect light to said photo detector.

15. The apparatus of claim 1, further comprising a linear carriage, a dead stop and a mirror, wherein said microtome and mirror are mounted in and moved along said linear carriage and wherein said mirror is positioned against said dead stop when said microtome has completed a pass across the specimen.

16. An apparatus for simultaneous imaging of backscattered electrons and cathodoluminesence from a specimen in an electron microscope, comprising:
a focused ion beam (FIB) generator;
a light director;
a light detector;
a backscattered electron detector;
wherein said FIB generator directs a beam to mill a surface of the specimen and wherein said light director is positioned to direct light from said surface to said light detector after said beam has milled said surface.

17. The apparatus of claim 16, wherein said beam also mills structures for reflecting light to said light director and wherein a reflective surface is deposited onto surfaces of said milled structures by introduction of localized gas in combination with said FIB.

18. The apparatus of claim 3, wherein said backscattered electron detector is mounted in a lens of the electron microscope.

19. The apparatus of claim 1, wherein said light detector is mounted in a support for said microtome and in the path of an electron beam of the electron microscope.

20. The apparatus of claim 1, wherein the specimen and a specimen support are at least partially transparent and wherein said light detector detects light internally reflected by said the specimen support.

21. The apparatus of claim 20, further comprising a highly reflective surface positioned above the specimen to enhance the amount of light reflected to said light detector.
